(19) United States
(12) Patent Application Publication
(10) Pub. No.: US 2015/0055671 A1
(43) Pub. Date: Feb. 26, 2015

(54) PHOTONIC DEVICES WITH EMBEDDED HOLE INJECTION LAYER TO IMPROVE EFFICIENCY AND DROOP RATE

(71) Applicant: TSMC Solid State Lighting Ltd., Hsinchu (TW)

(72) Inventors: Zhen-Yu Li, Zhuqi Township (TW); Tzu-Te Yang, Yuanli Township (TW); Hon-Way Lin, Hsinchu City (TW); Chung-Pao Lin, New Taipei City (TW); Kuan-Chun Chen, Taichung City (TW); Ching-Yu Chen, Hsinchu City (TW); You-Da Lin, Douliou City (TW); Hao-Chung Kuo, Tsu-bai City (TW)

(21) Appl. No.: 14/533,219

(22) Filed: Nov. 5, 2014

Related U.S. Application Data
(62) Division of application No. 13/616,345, filed on Sep. 14, 2012.

(51) Int. Cl. H01S 5/20; H01L 33/06; H01S 5/343; H01S 5/30; H01L 33/14; H01L 33/30

(52) U.S. Cl. CPC H01S 5/2013; H01L 33/145; H01L 33/305; H01S 5/34333; H01S 5/3063; H01L 33/06
USPC 372/45.012; 257/13; 438/45

(57) ABSTRACT

The present disclosure involves a light-emitting device. The light-emitting device includes an n-doped gallium nitride (n-GaN) layer located over a substrate. A multiple quantum well (MQW) layer is located over the n-GaN layer. An electron-blocking layer is located over the MQW layer. A p-doped gallium nitride (p-GaN) layer is located over the electron-blocking layer. The light-emitting device includes a hole injection layer. In some embodiments, the hole injection layer includes a p-doped indium gallium nitride (p-InGaN) layer that is located in one of the three following locations: between the MQW layer and the electron-blocking layer; between the electron-blocking layer and the p-GaN layer; and inside the p-GaN layer.

### PRIORITY DATA

The present application is a divisional application of U.S. patent application Ser. No. 13/616,345, filed on Sep. 14, 2012, the disclosure of which is hereby incorporated by reference in its entirety.

### TECHNICAL FIELD

The present disclosure relates generally to III-V group compound devices, and more particularly, to improving the efficiency and droop rate of III-V group compound devices such as gallium nitride (GaN) devices.

### BACKGROUND

The semiconductor industry has experienced rapid growth in recent years. Technological advances in semiconductor materials and design have produced various types of devices that serve different purposes. The fabrication of some types of these devices may require forming one or more III-V group compound layer on a substrate, for example forming a gallium nitride layer on a substrate. Devices using III-V group compounds may include light-emitting diode (LED) devices, laser diode (LD) devices, radio frequency (RF) devices, high electron mobility transistor (HEMT) devices, and/or high power semiconductor devices. Some of these devices, such as LED devices and LD devices, are configured to emit light due to electron-hole recombination when a voltage is applied.

However, traditional LED and LD devices have poor hole injection rates and poor hole spreading, which lead to reduced output power and large efficiency droop for the LED and LD devices.

Therefore, while existing LED and LD devices have been generally adequate for their intended purposes, they have not been entirely satisfactory in every aspect. LED and LD devices having better hole injection and hole spreading capabilities continue to be sought.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-2 and 7-9 are diagrammatic fragmentary cross cross-sectional side views of example LED structures according to various aspects of the present disclosure.

FIGS. 3-6 are graphs illustrating experimental data according to various aspects of the present disclosure.

FIG. 10 is a diagrammatic fragmentary cross-sectional side view of an example LED lighting apparatus according to various aspects of the present disclosure.

FIG. 11 is a diagrammatic view of a lighting module that includes the LED lighting apparatus of FIG. 7 according to various aspects of the present disclosure.

FIG. 12 is diagrammatic fragmentary cross cross-sectional side views of an example LD structures according to various aspects of the present disclosure.

FIG. 13 is a flowchart illustrating a method of fabricating a photonic device with an embedded hole injection layer according to various aspects of the present disclosure.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the terms “top,” “bottom,” “under,” “over,” and the like are used for convenience and are not meant to limit the scope of embodiments to any particular orientation. Various features may also be arbitrarily drawn in different scales for the sake of simplicity and clarity. In addition, the present disclosure may repeat reference numerals and/or letters in the various examples. This repetition is for the purpose of simplicity and clarity and does not in itself necessarily dictate a relationship between the various embodiments and/or configurations discussed.

As semiconductor fabrication technologies continue to advance, III-V group compounds (also referred to as III-V family compounds or group III-V compounds) have been utilized to produce a variety of devices, such as light-emitting diode (LED) devices, laser diode (LD) devices, radio frequency (RF) devices, high electron mobility transistor (HEMT) devices, and high power semiconductor devices. A III-V compound contains an element from a “III” group (or family) of the periodic table, and another element from a “V” group (or family) of the periodic table. For example, the III group elements may include Boron, Aluminum, Gallium, Indium, and Titanium, and the V group elements may include Nitrogen, Phosphorous, Arsenic, Antimony, and Bismuth.

Some of these III-V group compound devices, such as LEDs and LDs, utilize the electron-hole recombination when a voltage is applied to emit radiation. The radiation may include different colors of light in a visible spectrum, as well as radiation with ultraviolet or infrared wavelengths. Compared to traditional light sources (e.g., incandescent light bulbs), LEDs and LDs offer advantages such as smaller size, lower energy consumption, longer lifetime, variety of available colors, and greater durability and reliability. These advantages, as well as advancements in LED and LD fabrication technologies that have made LEDs and LDs cheaper and more robust, have added to the growing popularity of LEDs and LDs in recent years.

Nevertheless, existing LEDs and LDs may have certain shortcomings. One such shortcoming is that the existing LEDs and LDs may have poor hole injection and poor hole spreading, leading to inadequate electron-hole recombination. This causes output power of the LED or the LD to be reduced, as well as a potentially large efficiency droop.

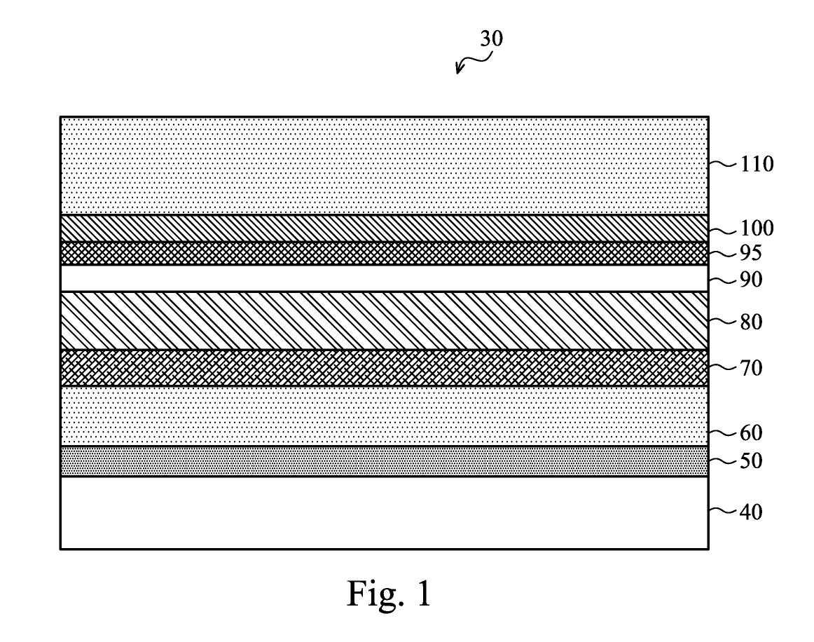

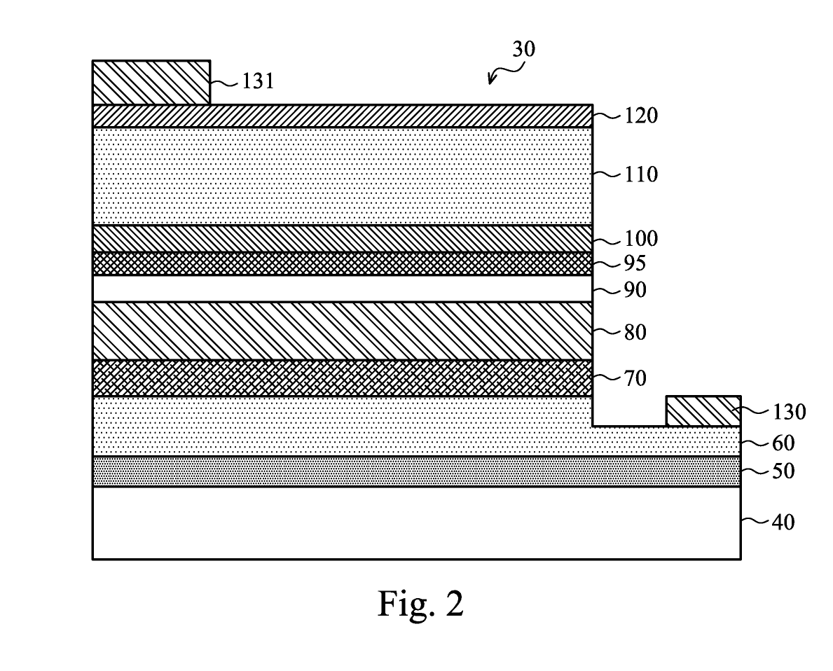

According to various aspects of the present disclosure, described below is a photonic device having improved hole injection and hole spreading, which improves electron-hole recombination so as to increase output power and to reduce the efficiency droop associated with existing LEDs and LDs. In some embodiments, the photonic device includes a horizontal LED. In some embodiments, the photonic device includes a vertical LED. FIGS. 1 to 2 are diagrammatic cross-sectional side views of a portion of the LEDs at various fabrication stages. FIGS. 1 to 2 have been simplified for a better understanding of the inventive concepts of the present disclosure.

Referring to FIG. 1, a horizontal LED 30 is illustrated. The horizontal LED 30 includes a substrate 40. The substrate 40 is a portion of a wafer. In some embodiments, the substrate 40 includes a sapphire material. In some other embodiments, the substrate 40 includes a silicon material. In some other embodiments, the substrate 40 includes a bulk III-V type compound, for example a bulk gallium nitride. In yet other embodiments, the substrate 40 may include a gallium nitride layer, a bonding wafer (which may include sapphire, silicon, Mullite, Su-Mullite, Quartz, Mo, and so on), and a dielectric layer (e.g., silicon oxide) bonded between the gallium nitride layer and the bonding wafer.

The substrate 40 may have a thickness that is in a range from about 50 microns (um) to about 1000 um. In some embodiments, a low temperature buffer film may be formed over the substrate 40. For reasons of simplicity, however, the low temperature buffer film is not illustrated herein.

An undoped semiconductor layer 50 is formed over the substrate 40. The undoped semiconductor layer 50 is free of a p-type dopant or an n-type dopant. In some embodiments, the undoped semiconductor layer 50 includes a compound that contains an element from the “III” group (or family) of the periodic table, and another element from the “V” group (or family) of the periodic table. In the illustrated embodiments, the undoped semiconductor layer 50 includes an undoped gallium nitride (GaN) material.

The undoped semiconductor layer 50 can also serve as a buffer layer (for example, to reduce stress) between the substrate 40 and layers that will be formed over the undoped semiconductor layer 50. To effectively perform its function as a buffer layer, the undoped semiconductor layer 50 has reduced dislocation defects and good lattice structure quality. In certain embodiments, the undoped semiconductor layer 50 has a thickness that is in a range from about 1 um to about 5 um.

A doped semiconductor layer 60 is formed over the undoped semiconductor layer 50. The doped semiconductor layer 60 is formed by an epitaxial growth process known in the art. In the illustrated embodiments, the doped semiconductor layer 60 is doped with a n-type dopant, for example Carbon (C) or Silicon (Si). In alternative embodiments, the doped semiconductor layer 60 may be doped with a p-type dopant, for example Magnesium (Mg). The doped semiconductor layer 60 includes a III-V group compound, which is gallium nitride in the present embodiment. Thus, the doped semiconductor layer 60 may also be referred to as a doped gallium nitride layer. In some embodiments, the doped semiconductor layer 60 has a thickness that is in a range from about 2 um to about 6 um.

A pre-strained layer 70 is formed on the doped semiconductor layer 60. The pre-strained layer 70 may be doped with an n-type dopant such as Silicon. In various embodiments, the pre-strained layer 70 may contain a plurality of pairs (for example 20-40 pairs) of interleaving InₓGa₁₋ₓN and GaN sub-layers, where x is greater or equal to 0 but less or equal to 1. The pre-strained layer 70 may serve to release strain and reduce a quantum-confined Stark effect (QCSE)—describing the effect of an external electric field upon the light absorption spectrum of a quantum well layer that is formed thereabove (i.e., the MQW layer 80 discussed below). In some embodiments, the InₓGa₁₋ₓN sub-layer may have a thickness in a range from about 0.5 nanometers (nm) to about 2 nm, the GaN sub-layer may have a thickness in a range from about 1 nm to about 7 nm, and the pre-strained layer 70 may have an overall thickness in a range from about 30 nm to about 80 nm.

A multiple-quantum well (MQW) layer 80 is formed over the pre-strained layer 70. The MQW layer 80 includes a plurality of alternating (or periodic) active and barrier sub-layers. The active sub-layers include indium gallium nitride (InₓGa₁₋ₓN ), and the barrier sub-layers include gallium nitride (GaN). For example, the MQW layer 80 may include 6-13 pairs of interleaving barrier sub-layers and active sub-layers. The barrier sub-layers may each have a thickness in a range from about 2 nm to about 5 nm, and the active sub-layers may each have a thickness in a range from about 4 nm to about 17 nm.

In some embodiments, a barrier layer 90 is formed over the MQW layer 80. The barrier layer 90 may contain a III-V group compound, for example InₓGa_{1-x-y}N , where both x and y are greater or equal to 0 but less or equal to 1. The barrier layer 90 may be considered to be a part of the MQW layer 80 as well. In that sense, the barrier layer 90 serves as the topmost barrier sub-layer of the MQW layer 80. Therefore, the barrier layer 90 may also be referred to as a “last barrier layer.” In some embodiments, the barrier layer 90 has a thickness in a range from about 4 nm to about 25 nm.

In the embodiment illustrated, a hole injection layer 95 is formed over the barrier layer 90. The hole injection layer 95 may be formed by an epitaxial growth process known in the art. In some embodiments, the hole injection layer 95 contains a p-type doped InₓGa₁₋ₓN , where x is greater or equal to 0 but less or equal to 1. For example, x may be between about 0.1 and 0.3. The p-type dopant may be Magnesium (Mg). The hole injection layer 95 may have a thickness that is less than about 100 nm. The presence of the hole injection layer 95 improves the hole injection rate and enhances the hole spreading in the LED 30. This is discussed in more detail below.

An electron blocking layer 100 may optionally be formed over the hole injection layer 95. The electron blocking 100 layer helps confine electron-hole carrier recombination within the MQW layer 80, which may improve quantum efficiency of the MQW layer 80 and reduce radiation in undesired bandwidths. In some embodiments, the electron blocking layer 100 may include a doped InₓAl_{y}Ga_{1-x-y}N material, where x and y are both greater or equal to 0 but less or equal to 1, and the dopant may include a p-type dopant such as Magnesium. The electron blocking layer 100 may have a thickness in a range from about 7 nm to about 25 nm.

A doped semiconductor layer 110 is formed over the electron blocking layer 100 (and thus over the MQW layer 80). The doped semiconductor layer 110 is formed by an epitaxial growth process known in the art. In some embodiment, the doped semiconductor layer 110 is doped with a dopant having an opposite (or different) type of conductivity from that of the doped semiconductor layer 60. Thus, in the embodiment where the doped semiconductor layer 60 is doped with an n-type dopant, the doped semiconductor layer 110 is doped with a p-type dopant. The doped semiconductor layer 110 includes a III-V group compound, which is a gallium nitride compound in the illustrated embodiments. Thus, the doped semiconductor layer 110 may also be referred to as a doped gallium nitride layer. In some embodiments, the doped semiconductor layer 110 has a thickness that is in a range from about 150 nm to about 200 nm.

A core portion of the LED 30 is created by the disposition of the MQW layer 80 between the doped layers 60 and 110. When an electrical voltage (or electrical charge) is applied to the doped layers of the LED 30, the MQW layer 80 emits radiation such as light. The color of the light emitted by the MQW layer 80 corresponds to the wavelength of the radiation. The radiation may be visible, such as blue light, or invisible, such as ultraviolet (UV) light. The wavelength of the light (and hence the color of the light) may be tuned by varying the composition and structure of the materials that make up the MQW layer 80.

Additional processes may be performed to complete the fabrication of the LED 30. For example, referring to FIG. 2, an electrically-conductive contact layer 120 may be formed over the doped-semiconductor layer 110. A portion of the layer 60 is etched away so that a part of the doped semiconductor layer 60 is exposed. Metal contacts 130-131 may then be formed on the surface of the exposed doped semiconductor layer 60 and on the surface of the contact layer 120, respectively. The metal contacts 130-131 are formed by one or more deposition and patterning processes. The metal contacts 130-131 allow electrical access to the doped semiconductor layer 60 and to the doped semiconductor layer 110, respectively.

As discussed above, existing MQWs may have inadequate electron-hole recombination rates. As a result, output power for existing LEDs may be low, and there may be a large efficiency droop as well. To overcome these problems plaguing existing LEDs, the LED 30 of the present disclosure utilizes the hole injection layer 95 to improve the electron-hole recombination. In more detail, the decay of carrier concentration is a function of distance or location within the LED. In the case of holes, its concentration is generally the greatest near the p-doped semiconductor layer 110 and the lowest near the n-doped semiconductor layer 60 (both shown in FIGS. 1-2). The decay of the hole concentration may be exponential, that is, the decay of the hole concentration will speed up drastically the farther it gets from the p-doped semiconductor layer 110. Also for conventional LEDs, holes cannot be easily moved (i.e., low mobility), especially under high current conditions. Due to at least the reasons discussed above, traditional LEDs may have very uneven hole distribution throughout the MQW layer, and therefore have inadequate electron-hole recombination in certain parts of the LED. This leads to reduced output power and a large droop for the conventional LED.

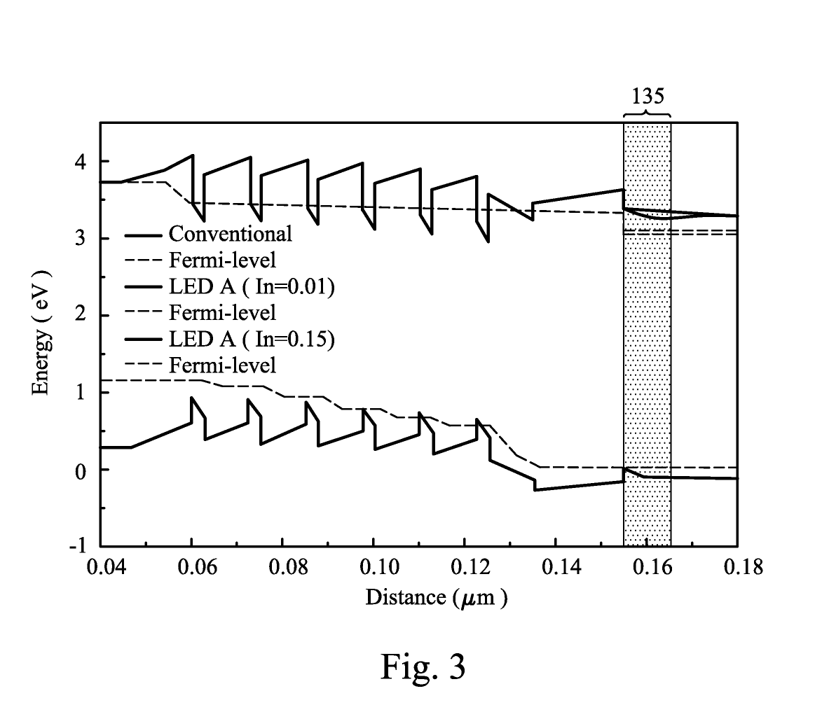

Here, the presence of the hole injection layer 95 substantially improves the distribution of holes. Referring to FIG. 3, an energy band diagram is illustrated for an LED. The X-axis of the energy band diagram represents distance across the LED (i.e., different LED depths), and the Y-axis of the energy band diagram represents the energy. The location of the hole injection layer 95 is represented by a well 135 shown in the energy band diagram of FIG. 3. The holes will be trapped in the well 135 (i.e., trapped in the hole injection layer 95). For conventional LEDs lacking the hole injection layer 95, the hole concentration in a region corresponding to the well 135 would have been too low. In comparison, the hole injection layer 95 may cause the holes to spread more throughout the LED, thereby making the hole distribution more even. This leads to better electron-hole recombination in greater areas of the LED. As a result, light output power and droop are both substantially improved.

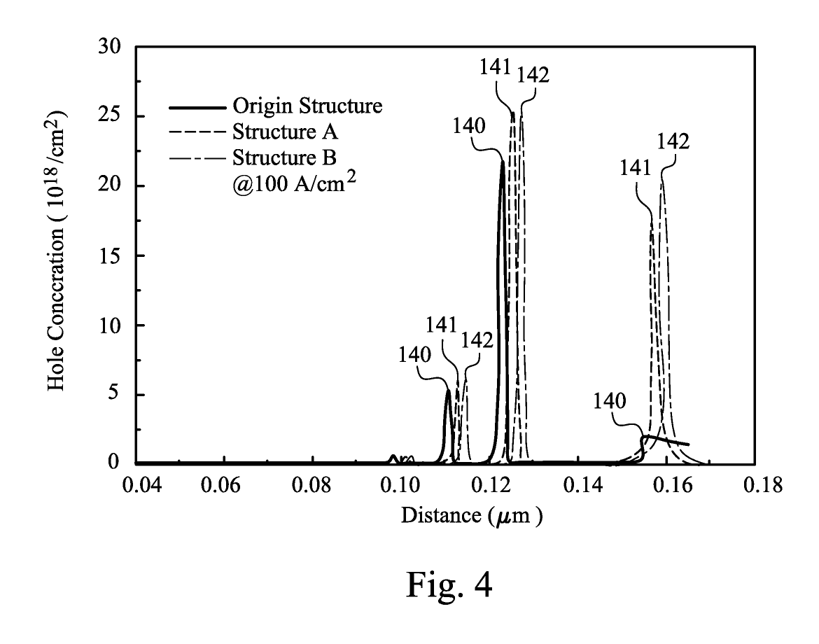

The improved hole concentration offered by the present disclosure is also visually illustrated in FIG. 4, which is a graph showing how hole concentration in the Y-axis varies with respect to distance (i.e., across the LED vertically as shown in FIGS. 1-2) in the X-axis. The graph includes experimental data 140 representing a conventional LED, and experimental data 141 and 142 representing two embodiments of the LED 30 of the present disclosure. Both embodiments utilize a p-doped hole injection layer that contains p-doped InGaN. For the embodiment represented by experimental data 141, the indium content of the InGaN is about 0.01. For the embodiment represented by experimental data 142, the indium content of the InGaN is about 0.015.

As is clearly shown in FIG. 4, the embodiments of the present disclosure (i.e., experimental data 141-142) have significantly higher hole concentrations compared to the conventional LED (experimental data 140). This is particularly true around the distance 0.16, which corresponds to the well 135 of FIG. 3 discussed above (i.e., the location of the LED where the hole injection layer is embedded). Thus, experimental results support the theory that by adding the hole injection layer, hole injection rate is improved, as is the hole spreading across different depths of the LED.

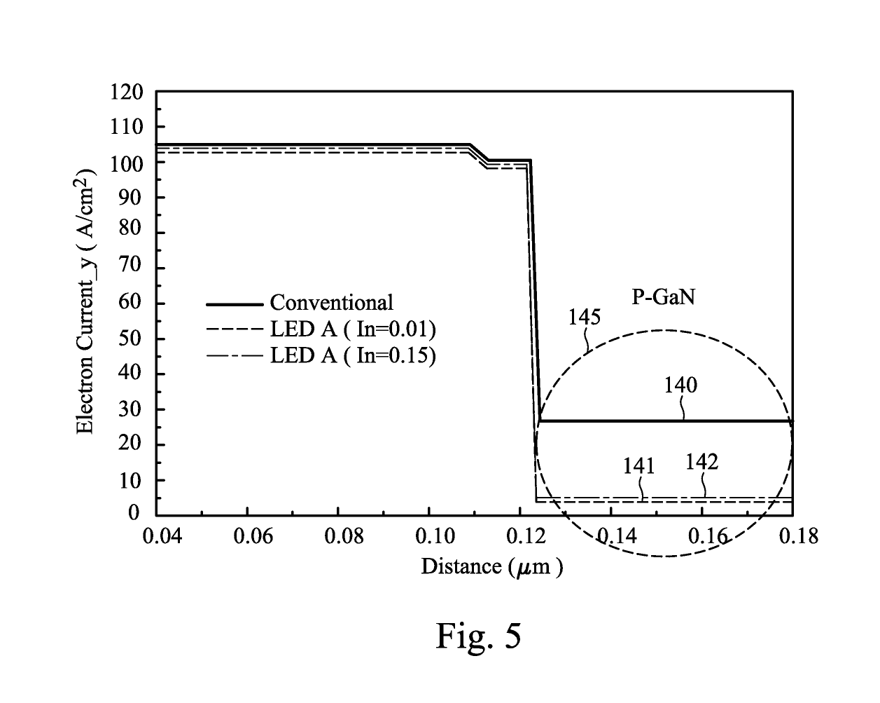

The present disclosure also reduces electron leakage. This is visually illustrated in FIG. 5, which is a graph showing how electron current (Y-axis) varies with respect to distance (i.e., across the LED vertically as shown in FIGS. 1-2) in the X-axis. Once again, the graph includes experimental data 140 representing the conventional LED, and experimental data 141 and 142 representing the two embodiments of the LED 30 of the present disclosure.

As is clearly shown in a region 145 of the LED in FIG. 5, the embodiments of the present disclosure (i.e., experimental data 141-142) have significantly lower electron currents compared to the conventional LED (experimental data 140). The region 145 overlaps with the well 135 discussed above, where the hole injection layer is located. The reduced electron current in the region 145 as shown in FIG. 5 indicates that more electrons have been recombined with holes in other light-emitting areas of the LED, thereby producing a greater amount of light. The reduced electron current in the region 145 also means that fewer electrons will leak out of the light-emitting regions. This in turn improves the droop efficiency (i.e., lowers the droop) at high injection currents.

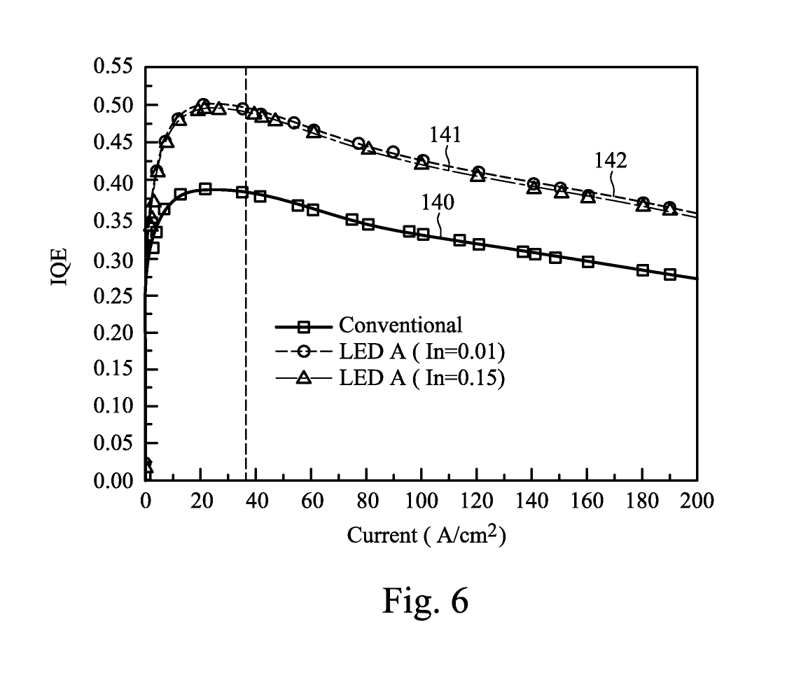

The improved droop efficiency offered by the present disclosure is illustrated is FIG. 6, which is a plot of quantum efficiency versus current density. In more detail, the X-axis of FIG. 6 represents current density, and the Y-axis of FIG. 6 represents quantum efficiency. Once again, shown in FIG. 6 are experimental data 140 (representing conventional LED) and experimental data 140-141 (representing embodiments of the LED 30 of the present disclosure). The conventional LED and the embodiments of the present disclosure all experience droop, represented by the fact that the quantum efficiency begins to decrease even as current increases. Nevertheless, the embodiments of the present disclosure still have higher quantum efficiency than the conventional LED throughout substantially all ranges of current (represented by the fact that experimental data 141-142 are greater than the experimental data 140 in FIG. 6). In other words, even though the present disclosure does not completely eliminate the undesirable droop, its droop performance is still much improved compared to the conventional LED.

It is understood that FIGS. 3-6 are merely example experimental results. Other experimental results may vary somewhat from those shown in FIGS. 3-6 without departing from the spirit and the scope of the present disclosure.

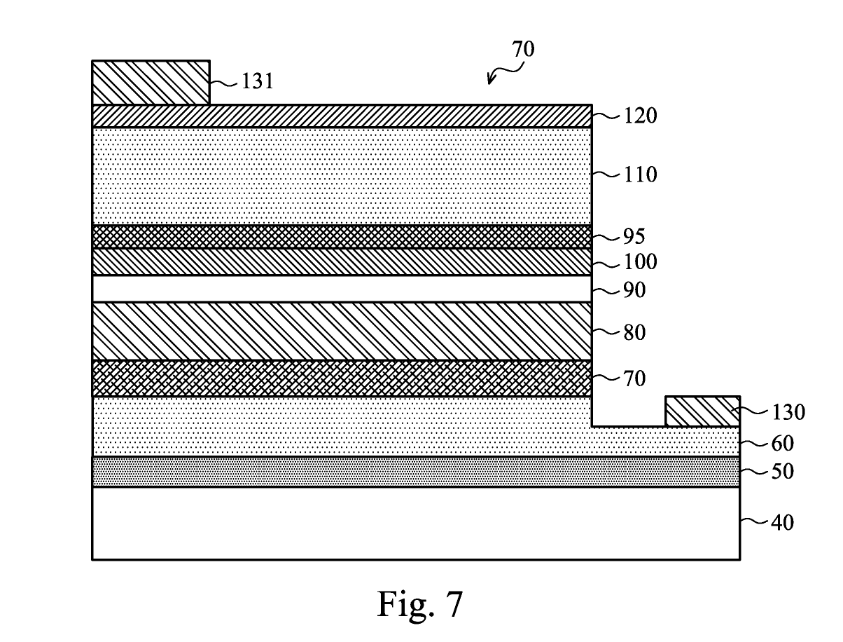

It is understood that the location of the hole injection layer 95 may be somewhat flexible, meaning it does not necessarily need to be disposed between the last barrier layer 90 (i.e., the topmost sub-layer of the MQW layer 80) and the electron-blocking layer 100. Referring to FIG. 7, the hole injection layer 95 may be disposed between the electron-blocking layer 100 and the doped semiconductor layer 110 in an alternative embodiment. Experimental results show the change in location of the hole injection layer 95 does not affect the hole injection or hole spreading performance too much. Stated differently, the embodiment shown in FIG. 7 still offers substantially the same hole injection and hole spreading advantages discussed above.

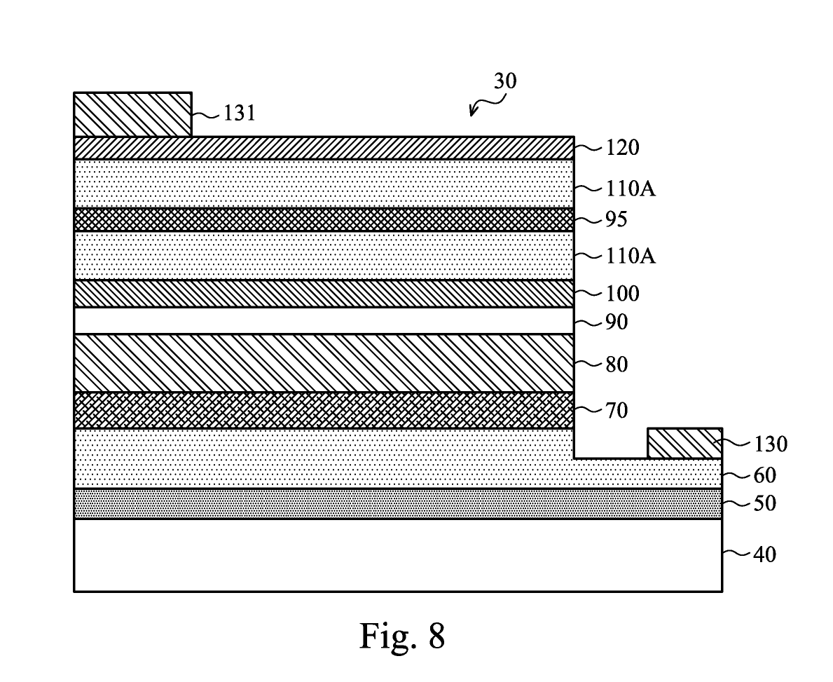

Also referring to FIG. 8, the hole injection layer 95 may be disposed inside the doped semiconductor layer 110 in yet another alternative embodiment. In other words, the formation of the doped semiconductor layer 110 may be broken into two steps. As the first step, a first portion of the doped semiconductor layer 110A may be epi-grown over the electron-blocking layer 100. The hole injection layer 95 is then grown on the first portion of the doped semiconductor layer 110A. Thereafter, a second portion of the doped semiconductor layer 110B is epi-grown over the hole injection layer 95. In this manner, the hole injection layer 95 may be formed “inside” the doped semiconductor layer 110. Once again, experimental results confirm that the change in location of the hole injection layer 95 does not affect the hole injection or hole spreading performance too much.

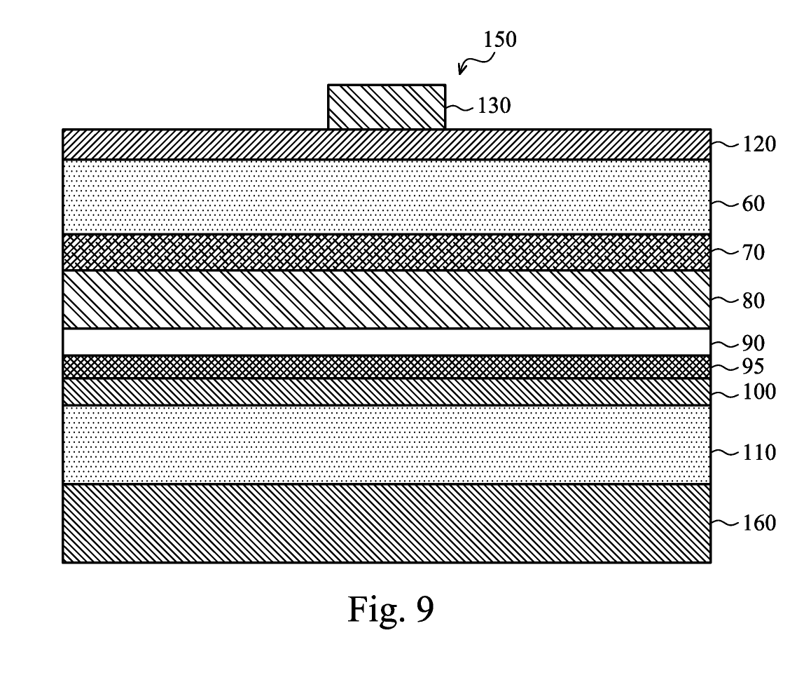

The various embodiments of the LED 30 having the hole injection layer 95 and illustrated in FIGS. 1-2 and 7-8 pertain to a horizontal LED. Similarly, a vertical LED may also be fabricated to incorporate the hole injection layer 95. For example, FIG. 9 illustrates an example of such vertical LED 150. Similar components in the vertical and horizontal LEDs are labeled the same for reasons of consistency and clarity.

Referring to FIG. 9, the vertical LED 150 has a submount 160. The submount 160 contains a metal material in the illustrated embodiments. In other embodiments, the submount 160 may include a silicon material. The doped semiconductor layer 110 is disposed on the submount 160. In the embodiment shown, the doped semiconductor layer 110 includes p-doped gallium nitride (p-GaN). The electron blocking layer 100 is disposed on the doped semiconductor layer 110. The hole injection layer 95 is disposed on the electron blocking layer. The last barrier layer 90 and the MQW layer 80 are disposed on the hole injection layer 95. The pre-strained layer 70 is disposed on the MQW layer 80. The doped semiconductor layer 60 is disposed on the pre-strained layer 70. In the embodiment shown, the doped semiconductor layer 60 includes n-doped gallium nitride (nGaN). The metal contact 131 is disposed on the contact layer 120. Electrical access to the doped layers of the LED 150 can be gained through the metal contact 131 and the submount 160.

Once again, though the embodiment shown in FIG. 9 illustrates the hole injection layer 95 as being disposed between the last barrier layer 90 and the electron blocking layer 100, it is understood that the hole injection layer 95 may be disposed between the electron blocking layer 100 and the doped semiconductor layer 110, or even inside the doped semiconductor layer 110 is alternative embodiments. These alternative embodiments are not specifically illustrated herein for reasons of simplicity.

To complete the fabrication of the horizontal LED 30 or the vertical LED 150, additional processes such as dicing, packaging, and testing processes may also be performed, but they are not illustrated herein for the sake of simplicity.

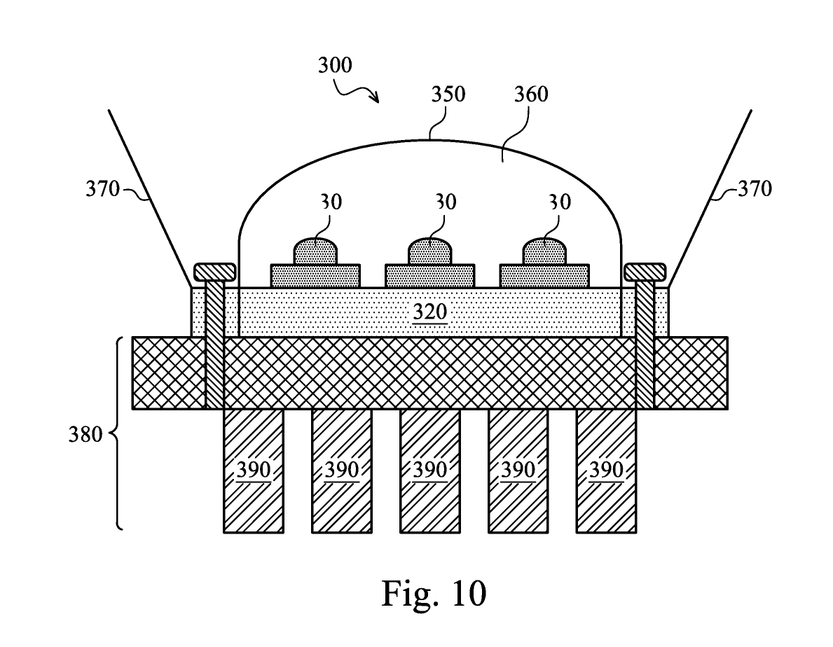

The LED 30 or the LED 150 having the hole injection layer 95 to improve hole injection rate and hole spreading as discussed above may be implemented as a part of a lighting apparatus. For example, the LED 30 (or the LED 150) may be implemented as a part of a LED-based lighting instrument 300, a simplified cross-sectional view of which is shown in FIG. 10. The embodiment of the LED-based lighting instrument 300 shown in FIG. 10 includes a plurality of LED dies. In other embodiments, the lighting instrument 300 may include a single LED die.

As discussed above, the LED dies include an n-doped III-V group compound layer, a p-doped III-V group compound layer, and a MQW layer disposed between the n-doped and p-doped III-V compound layers. The LED die also includes a hole injection layer, which may contain a magnesium-doped InGaN material as discussed above. The presence of the hole injection layer improves the hole injection and hole spreading performance of the LED, leading to better electron-hole recombination inside the LED die. Consequently, the LED dies herein offer less droop and better light output performance compared to traditional LED dies.

In some embodiments, the LED dies 30 each have a phosphor layer coated thereon. The phosphor layer may include either phosphorescent materials and/or fluorescent materials. The phosphor layer may be coated on the surfaces of the LED dies 30 in a concentrated viscous fluid medium (e.g., liquid glue). As the viscous liquid sets or cures, the phosphor material becomes a part of the LED package. In practical LED applications, the phosphor layer may be used to transform the color of the light emitted by an LED dies 30. For example, the phosphor layer can transform a blue light emitted by an LED die 30 into a different wavelength light. By changing the material composition of the phosphor layer, the desired light color emitted by the LED die 30 may be achieved.

The LED dies 30 are mounted on a substrate 320. In some embodiments, the substrate 320 includes a Metal Core Printed Circuit Board (MCPCB). The MCPCB includes a metal base that may be made of aluminum (or an alloy thereof). The MCPCB also includes a thermally conductive but electrically insulating dielectric layer disposed on the metal base. The MCPCB may also include a thin metal layer made of copper that is disposed on the dielectric layer. In alternative embodiments, the substrate 320 may include other suitable thermally conductive structures. The substrate 320 may or may not contain active circuitry and may also be used to establish interconnections. It is understood that in some embodiments, the LED dies 30 are attached to the substrate 320 without the submount 160 (described above with reference to FIG. 9).

The lighting instrument 300 includes a diffuser cap 350. The diffuser cap 350 provides a cover for the LED dies 30 therebelow. Stated differently, the LED dies 30 are encapsulated by the diffuser cap 350 and the substrate 320 collectively. In some embodiments, the diffuser cap 350 has a curved surface or profile. In some embodiments, the curved surface may substantially follow the contours of a semicircle, so that each beam of light emitted by the LED dies 30 may reach the surface of the diffuser cap 350 at a substantially right incident angle, for example, within a few degrees of 90 degrees. The curved shape of the diffuser cap 350 helps reduce Total Internal Reflection (TIR) of the light emitted by the LED dies 30.

The diffuser cap 350 may have a textured surface. For example, the textured surface may be roughened, or may contain a plurality of small patterns such as polygons or circles. Such textured surface helps scatter the light emitted by the LED dies 30 so as to make the light distribution more uniform. In some embodiments, the diffuser cap 350 is coated with a diffuser layer containing diffuser particles.

In some embodiments, a space 360 between the LED dies 30 and the diffuser cap 350 is filled by air. In other embodiments, the space 360 may be filled by an optical-grade silicone-based adhesive material, also referred to as an optical gel. Phosphor particles may be mixed within the optical gel in that embodiment so as to further diffuse light emitted by the LED dies 30.

Though the illustrated embodiment shows all of the LED dies 30 being encapsulated within a single diffuser cap 350, it is understood that a plurality of diffuser caps may be used in other embodiments. For example, each of the LED dies 30 may be encapsulated within a respective one of the plurality of diffuser caps.

The lighting instrument 300 may also optionally include a reflective structure 370. The reflective structure 370 may be mounted on the substrate 320. In some embodiments, the reflective structure is shaped like a cup, and thus it may also be referred to as a reflector cup. The reflective structure encircles or surrounds the LED dies 30 and the diffuser cap 350 in 360 degrees from a top view. From the top view, the reflective structure 370 may have a circular profile, a beehive-like hexagonal profile, or another suitable cellular profile encircling the diffuser cap 350. In some embodiments, the LED dies 30 and the diffuser cap 350 are situated near a bottom portion of the reflective structure 370. Alternatively stated, the top or upper opening of the reflective structure 370 is located above or over the LED dies 30 and the diffuser cap 350.

The reflective structure 370 is operable to reflect light that propagates out of the diffuser cap 350. In some embodiments, the inner surface of reflective structure 370 is coated with a reflective film, such as aluminum, silver, or alloys thereof. It is understood that the surface of the sidewalls of the reflective structure 370 may be textured in some embodiments, in a manner similar to the textured surface of the diffuser cap 350. Hence, the reflective structure 370 is operable to perform further scattering of the light emitted by the LED dies 30, which reduces glare of the light output of the lighting instrument 300 and makes the light output friendlier to the human eye. In some embodiments, the sidewalls of the reflective structure 370 have a sloped or tapered profile. The tapered profile of the reflective structure 370 enhances the light reflection efficiency of the reflective structure 370.

The lighting instrument 300 includes a thermal dissipation structure 380, also referred to as a heat sink 380. The heat sink 380 is thermally coupled to the LED dies 30 (which generate heat during operation) through the substrate 320. In other words, the heat sink 380 is attached to the substrate 320, or the substrate 320 is located on a surface of the heat sink 380. The heat sink 380 is configured to facilitate heat dissipation to the ambient atmosphere. The heat sink 380 contains a thermally conductive material, such as a metal material. The shape and geometries of the heat sink 380 are designed to provide a framework for a familiar light bulb while at the same time spreading or directing heat away from the LED dies 30. To enhance heat transfer, the heat sink 380 may have a plurality of fins 390 that protrude outwardly from a body of the heat sink 380. The fins 390 may have substantial surface area exposed to ambient atmosphere to facilitate heat transfer.

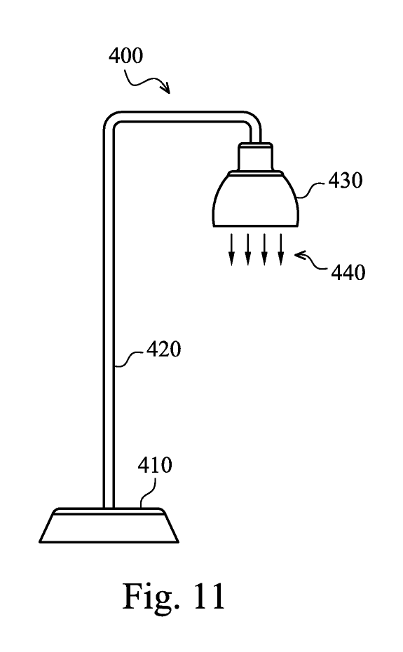

FIG. 11 illustrates a simplified diagrammatic view of a lighting module 400 that includes some embodiments of the lighting instrument 300 discussed above. The lighting module 400 has a base 410, a body 420 attached to the base 410, and a lamp 430 attached to the body 420. In some embodiments, the lamp 430 is a down lamp (or a down light lighting module). The lamp 430 includes the lighting instrument 300 discussed above with reference to FIG. 7. The lamp 430 is operable to efficiently project light beams 440. In addition, the lamp 430 can offer greater durability and longer lifetime compared to traditional incandescent lamps. It is understood that other lighting applications may benefit from using the LEDs of the present disclosure discussed above. For example, the LEDs of the present disclosure may be used in lighting applications including, but not limited to, vehicle headlights or taillights, vehicle instrument panel displays, light sources of projectors, light sources of electronics such as Liquid Crystal Display (LCD) televisions or LCD monitors, tablet computers, mobile telephones, or notebook/laptop computers.

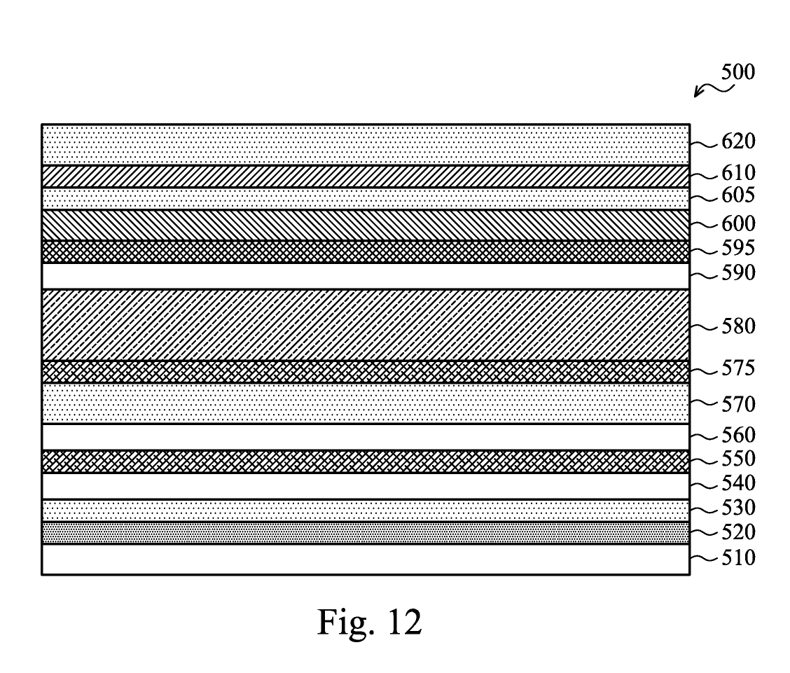

Though the hole injection layer implementation discussed above are illustrated using LEDs as an example, it is understood that a similar hole injection layer may also be implemented for laser diodes (LDs). FIG. 12 illustrates a simplified cross-sectional side view of an embodiment of the LD 500 according to various aspects of the present disclosure.

The LD 500 includes a substrate 510, which is a silicon substrate in the embodiment shown. A III-V group compound layer 520 is formed over the substrate 510. In some embodiments, the III-V compound layer 520 includes AlN. Another III-V compound layer 530 is formed over the III-V compound layer 510. In some embodiments, the III-V compound layer 530 includes a plurality of sub-layers, for example AlGaN sub-layers. The thicknesses for these sub-layers may increase, and the aluminum content for these sub-layers may decrease, as the sub-layer go up (i.e., farther away from the substrate 510).

A III-V compound epi layer 540 is then formed over the III-V compound layer 530. In some embodiments, the III-V compound epi layer 540 may include GaN. Thereafter, an AlN layer or an AlGaN layer 550 is formed over the III-V compound epi layer 540. Another III-V compound epi layer 560 is then formed over the AlN or AlGaN layer 550.

An n-doped III-V compound layer 570 is then formed over the III-V compound epi layer 560. In some embodiments, the n-doped III-V compound layer 570 includes n-type doped GaN. A plurality of other layers 575 may be formed over the n-doped III-V compound layer 570, for example including an n-doped InGaN layer, a cladding layer containing n-doped InAlGaN, and a guiding layer containing n-doped InGaN.

Thereafter, a MQW layer 580 may be formed over the layer 575 (and over the n-doped III-V compound layer 570). As discussed above, the MQW layer includes interleaving barrier layers and active layers, which may include InGaN and GaN, respectively. A last barrier layer 590 is formed over the MQW layer 580. The last barrier layer 590 contains InAlGaN and may be also considered the topmost barrier layer of the MQW layer 580.

A hole injection layer 595 is formed over the last barrier layer 590. The hole injection layer 595 is similar to the hole injection layer 95 discussed above with reference to the LED-based implementations. Once again, the presence of the hole injection layer 595 leads to hole injection and hole spreading performance of the LD 500. As a result, the LD 500 has a better light output and reduced droop.

An electron blocking layer 600 is formed over the MQW layer 80. In some embodiments, the electron blocking layer 600 includes p-doped InAlGaN. Thereafter, a guiding layer 605 is formed over the electron blocking layer 590. In some embodiments, the guiding layer 605 includes a p-doped InGaN. A cladding layer 610 is then formed over the guiding layer 605. In some embodiments, the cladding layer 610 includes a p-doped InAlGaN. A p-doped III-V compound layer 620 is then formed over the cladding layer 610. In some embodiments, the p-doped III-V compound layer 570 includes p-type doped GaN.

Though the embodiment of the LD 500 shows the hole injection layer 595 as being disposed between the last barrier layer 590 and the electron-blocking layer 600, it is understood that the hole injection layer 595 may be disposed differently in other embodiments of the LD 500. For example, in various other embodiments of the LD 500, the hole injection layer 595 may be disposed between the electron-blocking layer 600 and the guiding layer 605, or between the guiding layer 605 and the cladding layer 610, or between the cladding layer 610 and the p-doped III-V compound layer 620, or even inside the p-doped III-V compound layer 620. For reasons of simplicity, however, these other embodiments are not specifically illustrated herein.

The various layers of the LD 500 discussed above and shown in FIG. 12 are merely example layers. Other LDs may incorporate different layers depending on the design needs.

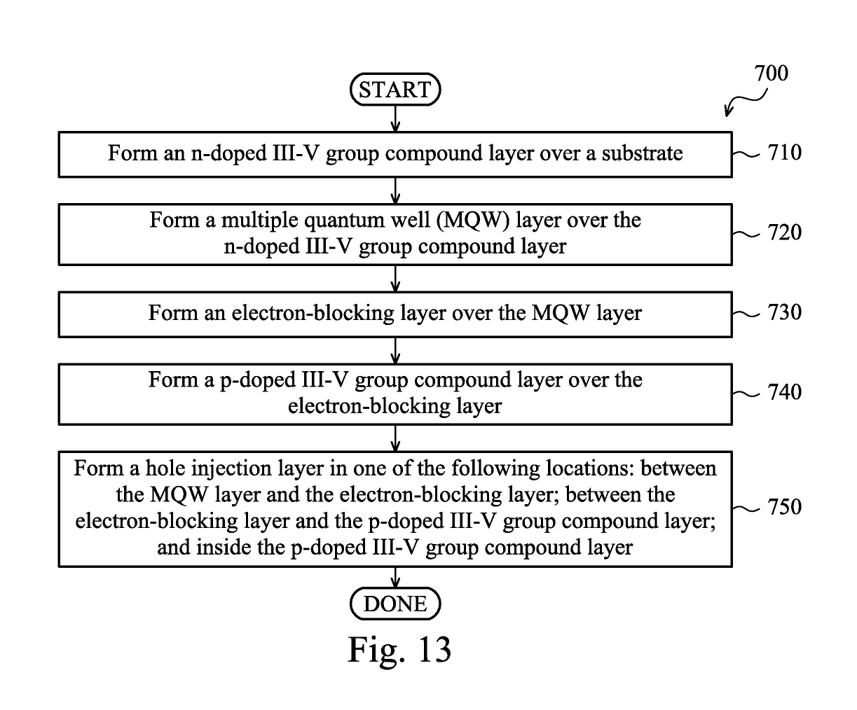

FIG. 13 is a flowchart illustrating a simplified method 700 of fabricating a photonic device having a hole injection layer according to the various aspects of the present disclosure. The photonic device may be a horizontal LED, a vertical LED, or an LD.

The method 700 includes a step 710, in which an n-doped III-V group compound layer is formed over a substrate. The method 700 includes a step 720, in which a multiple quantum well (MQW) layer is formed over the n-doped III-V group compound layer. The method 700 includes a step 730, in which an electron-blocking layer is formed over the MQW layer. The method 700 includes a step 740, in which a p-doped III-V group compound layer is formed over the electron-blocking layer. The method 700 includes a step 750, in which a hole injection layer is formed in one of the following locations: between the MQW layer and the electron-blocking layer; between the electron-blocking layer and the p-doped III-V group compound layer; and inside the p-doped III-V group compound layer. In some embodiments, the hole injection layer contains a p-doped III-V compound material different from the p-doped III-V group compound layer.

Additional processes may be performed before, during, or after the blocks 710-730 discussed herein to complete the fabrication of the photonic device. These other processes are not discussed in detail herein for reasons of simplicity.

One aspect the present disclosure involves a photonic device. The photonic device includes: an n-doped III-V group compound layer disposed over a substrate; a multiple quantum well (MQW) layer disposed over the n-doped III-V group compound layer; a p-doped III-V group compound layer disposed over the MQW layer; and a hole injection layer disposed between the MQW layer and the p-doped III-V group compound layer, wherein the hole injection layer contains a p-doped III-V compound material different from the p-doped III-V group compound layer.

In some embodiments, the p-doped III-V compound material of the hole injection layer includes magnesium-doped indium gallium nitride (InGaN).

In some embodiments, the hole injection layer is disposed inside the p-doped III-V group compound layer.

In some embodiments, the photonic device further includes an electron-blocking layer disposed between the MQW layer and the p-doped III-V group compound layer.

In some embodiments, the hole injection layer is disposed between the electron-blocking layer and the MQW layer.

In some embodiments, the hole injection layer is disposed between the electron-blocking layer and the p-doped III-V group compound layer.

In some embodiments, the electron-blocking layer contains a p-doped indium aluminum gallium nitride (InAlGaN) material.

In some embodiments, the n-doped III-V group compound layer and the p-doped III-V group compound layer include n-doped gallium nitride (n-GaN) and p-doped gallium nitride (p-GaN), respectively; and the MQW layer contains a plurality of interleaving indium gallium nitride (InGaN) and gallium nitride (GaN) sub-layers.

In some embodiments, the photonic device includes one of: a light-emitting diode (LED) and a laser diode (LD).

In some embodiments, the photonic device includes a lighting module having one or more dies, and wherein the n-doped and p-doped III-V group compound layers and the MQW layer are implemented in each of the one or more dies.

Another one aspect the present disclosure involves a light-emitting device. The light-emitting device includes: an n-doped gallium nitride (n-GaN) layer located over a substrate; a multiple quantum well (MQW) layer located over the n-GaN layer; an electron-blocking layer located over the MQW layer; a p-doped gallium nitride (p-GaN) layer located over the electron-blocking layer; and a p-doped indium gallium nitride (p-InGaN) layer embedded in one of the three following locations: between the MQW layer and the electron-blocking layer; between the electron-blocking layer and the p-GaN layer; and inside the p-GaN layer.

In some embodiments, the electron-blocking layer contains a p-doped indium aluminum gallium nitride (InAlGaN) material.

In some embodiments, the n-GaN layer, the MQW layer, the electron-blocking layer, the p-GaN layer, and the p-InGaN layer are parts of a light-emitting diode (LED) device.

In some embodiments, the n-GaN layer, the MQW layer, the electron-blocking layer, the p-GaN layer, and the p-InGaN layer are parts of a laser diode (LD) device.

In some embodiments, the p-InGaN layer has magnesium as a dopant; a concentration of the magnesium in the p-InGaN layer is in a range from about 1.0×10¹⁷ ions/centimeter³ to about 1.0×10¹⁹ ions/centimeter³; and a thickness of the p-InGaN layer is less than about 100 nanometers.

In some embodiments, the substrate includes one of: a gallium nitride substrate, a sapphire substrate, a silicon substrate, and a substrate including a dielectric layer sandwiched between a gallium nitride layer and a bonding wafer.

Yet another aspect of the present disclosure involves a method of fabricating a light-emitting device. The method includes: growing an n-doped III-V group compound layer over a substrate; growing a multiple quantum well (MQW) layer over the n-doped III-V group compound layer; growing an electron-blocking layer over the MQW layer; growing a p-doped III-V group compound layer over the electron-blocking layer; and forming a hole injection layer in one of the following locations: between the MQW layer and the electron-blocking layer; between the electron-blocking layer and the p-doped III-V group compound layer; and inside the p-doped III-V group compound layer; wherein the hole injection layer contains a p-doped III-V compound material different from the p-doped III-V group compound layer.

In some embodiments, the n-doped III-V group compound layer and the p-doped III-V group compound layer include n-doped gallium nitride (n-GaN) and p-doped gallium nitride (p-GaN), respectively; the MQW layer contains a plurality of interleaving indium gallium nitride (InGaN) and gallium nitride (GaN) sub-layers; the electron-blocking layer contains a p-doped indium aluminum gallium nitride (InAlGaN) material; and the hole injection layer contains magnesium-doped indium gallium nitride (InGaN).

In some embodiments, the growing the hole injection layer is performed in a manner so that: a concentration of the magnesium in the hole injection layer is in a range from about 1×10¹⁷ ions/centimeter³ to about 1.0×10¹⁹ ions/centimeter³; and a thickness of the hole injection layer is less than about 100 nanometers.

In some embodiments, the light-emitting device includes one of: a light-emitting diode (LED) and a laser diode (LD).

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A photonic device, comprising:
an n-doped III-V group compound layer disposed over a substrate;
a multiple quantum well (MQW) layer disposed over the n-doped III-V group compound layer;
an electron-blocking layer disposed over the MQW layer;
a p-doped III-V group compound layer disposed over the electron-blocking layer; and
a hole injection layer disposed inside the p-doped III-V group compound layer or in between the electron-blocking layer and the p-doped III-V group compound layer, wherein the hole injection layer contains a p-doped III-V group compound material different from the p-doped III-V group compound layer.

2. The photonic device of claim 1, wherein the p-doped III-V group compound material of the hole injection layer includes magnesium-doped indium gallium nitride (InGaN).

3. The photonic device of claim 2, wherein a concentration of the magnesium in the InGaN is in a range from about 1.0×10¹⁷ ions/centimeter³ to about 1.0×10¹⁹ ions/centimeter³.

4. The photonic device of claim 1, wherein a thickness of the hole injection layer is less than about 100 nanometers.

5. The photonic device of claim 1, wherein the substrate includes one of: a gallium nitride substrate, a sapphire substrate, a silicon substrate, and a substrate including a dielectric layer sandwiched between a gallium nitride layer and a bonding wafer.

6. The photonic device of claim 1, wherein the electron-blocking layer contains a p-doped indium aluminum gallium nitride (InAlGaN) material.

7. The photonic device of claim 1, wherein:
the n-doped III-V group compound layer and the p-doped III-V group compound layer include n-doped gallium nitride (n-GaN) and p-doped gallium nitride (p-GaN), respectively; and
the MQW layer contains a plurality of interleaving indium gallium nitride (InGaN) and gallium nitride (GaN) sub-layers.

8. The photonic device of claim 1, wherein the photonic device includes one of: a light-emitting diode (LED) and a laser diode (LD).

9. The photonic device of claim 1, wherein the hole injection layer is disposed inside the p-doped III-V group compound layer.

10. The photonic device of claim 1, wherein the photonic device includes a lighting module having one or more dies, and wherein the n-doped and p-doped III-V group compound layers and the MQW layer are implemented in each of the one or more dies.

11. A light-emitting device, comprising:
an n-doped gallium nitride (n-GaN) layer located over a substrate;
a multiple quantum well (MQW) layer located over the n-GaN layer;
an electron-blocking layer located over the MQW layer;
a p-doped gallium nitride (p-GaN) layer located over the electron-blocking layer; and
a p-doped indium gallium nitride (p-InGaN) layer embedded in one of the three following locations:
between the electron-blocking layer and the p-GaN layer; and
inside the p-GaN layer.

12. The light-emitting device of claim 11, wherein the electron-blocking layer contains a p-doped indium aluminum gallium nitride (InAlGaN) material.

13. The light-emitting device of claim 11, wherein the n-GaN layer, the MQW layer, the electron-blocking layer, the p-GaN layer, and the p-InGaN layer are parts of a light-emitting diode (LED) device.

14. The light-emitting device of claim 11, wherein the n-GaN layer, the MQW layer, the electron-blocking layer, the p-GaN layer, and the p-InGaN layer are parts of a laser diode (LD) device.

15. The light-emitting device of claim 11, wherein:
the p-InGaN layer has magnesium as a dopant;
a concentration of the magnesium in the p-InGaN layer is in a range from about 1.0×10¹⁷ ions/centimeter³ to about 1.0×10¹⁹ ions/centimeter³; and
a thickness of the p-InGaN layer is less than about 100 nanometers.

16. The light-emitting device of claim 11, wherein the substrate includes one of: a gallium nitride substrate, a sapphire substrate, a silicon substrate, and a substrate including a dielectric layer sandwiched between a gallium nitride layer and a bonding wafer.

17. A method of fabricating a light-emitting device, comprising:
growing an n-doped III-V group compound layer over a substrate;
growing a multiple quantum well (MQW) layer over the n-doped III-V group compound layer;
growing an electron-blocking layer over the MQW layer;
growing a p-doped III-V group compound layer over the electron-blocking layer; and
forming a hole injection layer in one of the following locations:
between the electron-blocking layer and the p-doped III-V group compound layer; and
inside the p-doped III-V group compound layer;
wherein the hole injection layer contains a p-doped III-V group compound material different from the p-doped III-V group compound layer.

18. The method of claim 17, wherein:
the n-doped III-V group compound layer and the p-doped III-V group compound layer include n-doped gallium nitride (n-GaN) and p-doped gallium nitride (p-GaN), respectively;
the MQW layer contains a plurality of interleaving indium gallium nitride (InGaN) and gallium nitride (GaN) sub-layers;
the electron-blocking layer contains a p-doped indium aluminum gallium nitride (InAlGaN) material; and
the hole injection layer contains magnesium-doped indium gallium nitride (InGaN).

19. The method of claim 17, wherein the growing the hole injection layer is performed in a manner so that:
a concentration of the magnesium in the hole injection layer is in a range from about 1.0×10¹⁷ ions/centimeter³ to about 1.0×10¹⁹ ions/centimeter³; and
a thickness of the hole injection layer is less than about 100 nanometers.

20. The method of claim 17, wherein the light-emitting device includes one of: a light-emitting diode (LED) and a laser diode (LD).
